(19) United States
(12) Patent Application Publication
(10) Pub. No.: US 2022/0190069 A1
(43) Pub. Date: Jun. 16, 2022

(54) DISPLAY DEVICE AND DEPOSITION MASK

(71) Applicant: SHARP KABUSHIKI KAISHA, Sakai City, Osaka (JP)

(72) Inventors: EIJI KOIKE, Sakai City, Osaka (JP); TOHRU SONODA, Sakai City, Osaka (JP); MASAHIRO INUZUKA, Sakai City, Osaka (JP); JUNYA SHIMADA, Sakai City, Osaka (JP)

(21) Appl. No.: 17/442,563

(22) PCT Filed: Mar. 27, 2019
(86) PCT No.: PCT/JP2019/013461

§ 371 Date: Sep. 23, 2021

(51) Int. Cl. H01L 27/32; H01L 51/52; H01L 51/00; H01L 51/56; C23C 16/04

(52) U.S. Cl. CPC H01L 27/3246; H01L 51/5253; H01L 51/001; H01L 2227/323; H01L 51/56; C23C 16/042; H01L 51/0011

(57) ABSTRACT

A display device includes an active matrix substrate; a light-emitting element layer including a plurality of first electrodes, a function layer, and a second electrode; and a sealing layer. The light-emitting element layer further includes an edge cover layer configured to cover an end portion of each one of the plurality of first electrodes. The edge cover layer includes a plurality of openings configured to expose the plurality of first electrodes included in a plurality of pixels. The plurality of openings include a first opening with a rectangular shape. A first individual vapor deposition film with a rectangular shape is formed on the first electrode covering the first opening. In the first individual vapor deposition film, projection portions projecting from sections corresponding to at least some opposing vertices of the first opening to an opposite side to the first opening are provided on the edge cover layer.

### TECHNICAL FIELD

The disclosure relates to a display device and a vapor deposition mask.

### BACKGROUND ART

In recent years, various display devices including a light-emitting element have been developed. Particularly, a display device including an organic light-emitting diode (OLED) and a display device including an inorganic light-emitting diode or a quantum dot light-emitting diode (QLED) have drawn a great deal of attention because these devices offer advantages such as lower power consumption, smaller thickness, and higher picture quality.

In the manufacture of a display device provided with an OLED or a display device provided with an inorganic light emitting diode or QLED, a fine metal mask (FMM), which is a vapor deposition mask, is used to separately pattern various types of vapor deposition material. However, for example, when separately patterning, the fine metal mask and the substrate need to be aligned with an accuracy of a few μm for each color. However, in a fine metal mask, when the mask sheet is set in a tensioned state, the shape of the opening may deform, and in a case where an opening with a deformed shape is used, a misalignment of the formation position of the vapor deposition film may occur, causing a fault such as a color mixing defect.

PTL 1 describes that, in a vapor deposition mask, wrinkles and deformation in the vapor deposition mask can be suppressed from occurring by providing a cutout portion or through-hole in regions other than the vapor deposition effective region, such as the peripheral region and the ear region.

### CITATION LIST

### Patent Literature

PTL 1: JP 2018-95958 A (published on Jun. 21, 2018)

### SUMMARY

### Technical Problem

However, in the case of the vapor deposition mask described in PTL 1, because the opening of the vapor deposition effective region through which the vapor deposition material passes is a rectangular shape and with no measures taken for the vapor deposition effective region through which the vapor deposition material passes, when the mask sheet is set in a tensioned state, the rectangular opening deforms, resulting in instances of the color mixing defect caused by misalignment occurring being unable to be reduced.

In light of the foregoing, the disclosure is directed at providing a display device having excellent display quality and a vapor deposition mask that can prevent deformation of an opening through which vapor deposition material passes when the mask sheet is set in a tensioned state.

### Solution to Problem

To solve the problem described above, a display device according to the disclosure is provided with a display region including a plurality of pixels and a frame region around the display region and includes:

an active matrix substrate including a transistor element;

a light-emitting element layer provided on the active matrix substrate and including a plurality of first electrodes, a function layer, and a second electrode in this order from the active matrix substrate side; and

a sealing layer provided on the light-emitting element layer,

wherein the light-emitting element layer further includes an edge cover layer configured to cover an end portion of each one of the plurality of first electrodes,

the edge cover layer includes a plurality of openings configured to expose the plurality of first electrodes included in the plurality of pixels,

the plurality of openings including a first opening with a rectangular shape,

a first individual vapor deposition film with a rectangular shape is formed on the first electrode covering the first opening, and

in the first individual vapor deposition film, projection portions projecting from sections corresponding to at least some opposing vertices of the first opening to an opposite side to the first opening are provided on the edge cover layer.

To solve the problem described above, a vapor deposition mask of the disclosure includes:

a mask frame with a frame-like shape; and

a mask sheet including a plurality of openings, the mask sheet being fixed to the mask frame,

wherein the plurality of openings of the mask sheet are openings with a rectangular shape, and

in the openings, cutout portions are provided at sections corresponding to at least some opposing vertices.

### Advantageous Effects of Disclosure

Provided is a display device having excellent display quality and a vapor deposition mask that can prevent deformation of an opening through which vapor deposition material passes when the mask sheet is set in a tensioned state.

### BRIEF DESCRIPTION OF DRAWINGS

FIG. 1(a) is a diagram illustrating a schematic configuration of a divided mask, FIG. 1(b) is an enlarged view of a C portion illustrated in (a) of FIG. 1, FIG. 1(c) is a diagram illustrating a schematic configuration of the vapor deposition mask according to the present embodiment, and FIG. 1(d) is an enlarged view of a D portion illustrated in (c) of FIG. 1.

FIG. 2(a) is a diagram illustrating a case in which the vapor deposition mask illustrated in (c) of FIG. 1 is disposed with respect to a blue pixel, FIG. 2(b) is a diagram for describing an increase in an alignment margin in a case of using the vapor deposition mask illustrated in (c) of FIG. 1.

FIG. 3(b) is a diagram illustrating a position for disposing the vapor deposition mask illustrated in (c) of FIG. 1 with respect to a blue pixel and a position for disposing another vapor deposition mask including rectangular openings including cutout portions according to the present embodiment with respect to a red pixel, FIG. 3(b) is a diagram illustrating a position for disposing the vapor deposition mask illustrated in (c) of FIG. 1 with respect to a blue pixel, a position for disposing another vapor deposition mask including rectangular openings including cutout portions according to the present embodiment with respect to a red pixel, and a position for disposing yet another vapor deposition mask including openings with respect to a green pixel.

FIGS. 4(a) and 4(b) are diagrams illustrating an arrangement of each of the color pixels in the display device of the present embodiment, the size of the rectangular openings including the cutout portions of the vapor deposition mask illustrated in (c) of FIG. 1 compared to the blue pixels, and the size of the rectangular openings including the cutout portion of another vapor deposition mask of the present embodiment compared to the red pixel.

FIGS. 5(a) to 5(f) are diagrams for describing the process for forming a vapor deposition film using the vapor deposition mask illustrated in (c) of FIG. 1, another vapor deposition mask including the rectangular openings including the cutout portions according to the present embodiment, and yet another vapor deposition mask including the openings, in this order.

FIG. 6(a) is a cross-sectional view of a display region of the display device according to the present embodiment. FIG. 6(b) is a plan view of the display device according to the present embodiment.

FIG. 7(a) is a diagram illustrating a schematic configuration of a divided mask provided in another vapor deposition mask according to the present embodiment, and FIG. 7(b) is an enlarged view of an E portion illustrated in (a) of FIG. 7.

FIG. 8(a) is a diagram illustrating a schematic configuration of a divided mask provided in yet another vapor deposition mask according to the present embodiment, and FIG. 8(b) is an enlarged view of an F portion illustrated in (a) of FIG. 8.

FIG. 9(a) is a diagram illustrating a schematic configuration of a divided mask provided in a vapor deposition mask according to a Comparative Example, FIG. 9(b) is an enlarged view of an M portion illustrated in (a) of FIG. 9, FIG. 9(c) is a diagram illustrating a schematic configuration of a vapor deposition mask according to the Comparative Example, and FIG. 9(d) is an enlarged view of an N portion illustrated in (c) of FIG. 9.

FIGS. 10(a) to 10(d) are diagrams for explaining the problem of using the vapor deposition mask according to the Comparative Example illustrated in FIG. 9(c).

FIGS. 11(a) to 11(d) are diagrams illustrating an active matrix substrate and a plurality of first electrodes and an edge cover layer provided on the active matrix substrate provided in the display device according to the present embodiment.

### DESCRIPTION OF EMBODIMENTS

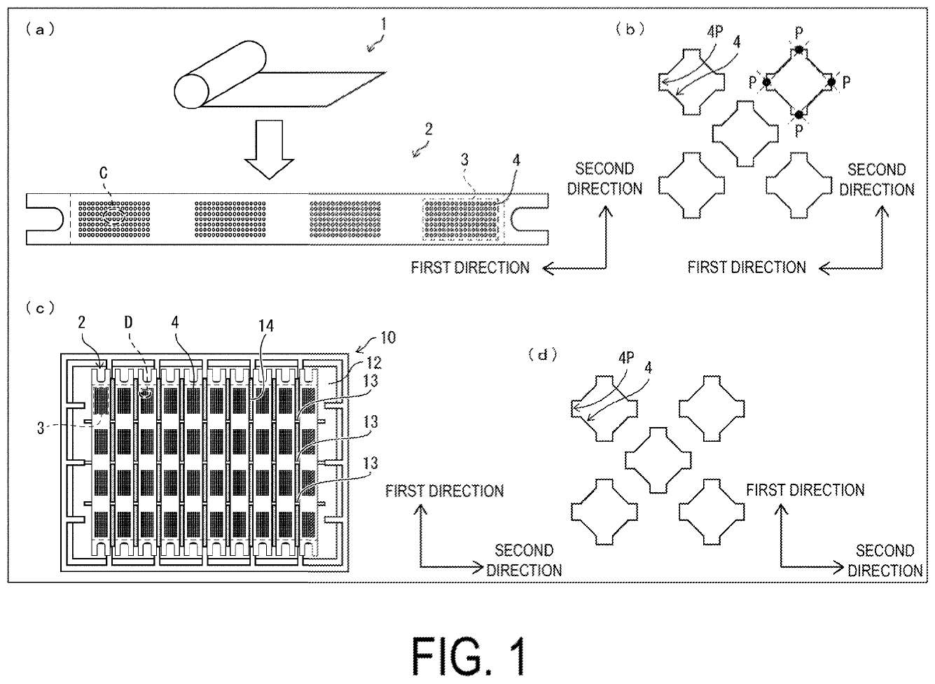

Embodiments of the disclosure will be described below with reference to FIGS. 1 to 11. Hereinafter, for convenience of description, components having the same functions as those described in a specific embodiment are denoted by the same reference numerals, and descriptions thereof may be omitted.

### First Embodiment

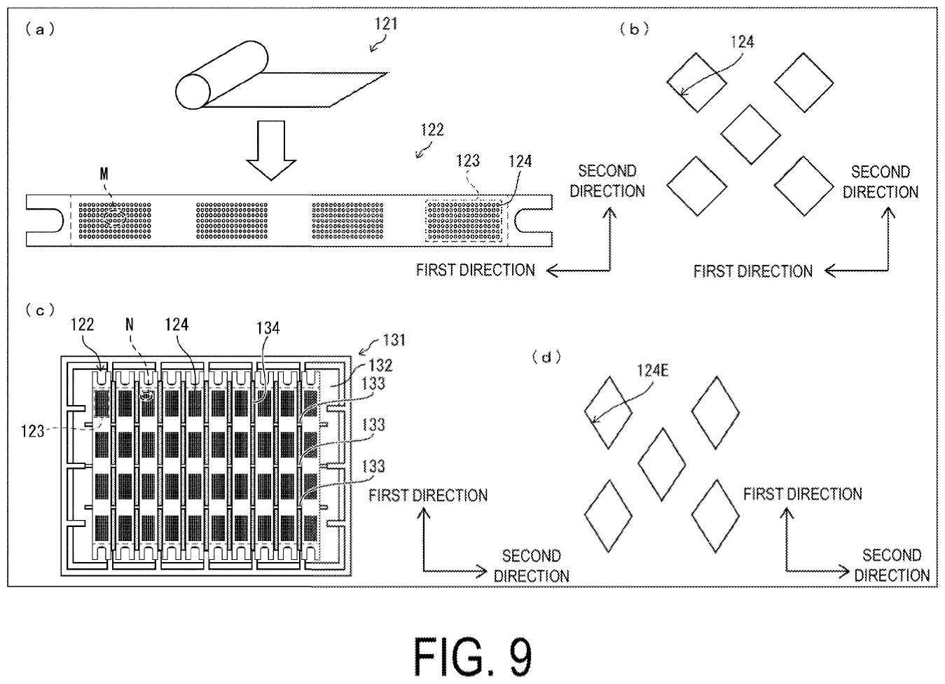

(a) of FIG. 9 is a diagram illustrating a schematic configuration of a divided mask 122 provided in a vapor deposition mask 131 according to a Comparative Example, (b) of FIG. 9 is an enlarged view of an M portion illustrated in (a) of FIG. 9, (c) of FIG. 9 is a diagram illustrating a schematic configuration of a vapor deposition mask 131 according to the Comparative Example, and (d) of FIG. 9 is an enlarged view of an N portion illustrated in (c) of FIG. 9.

As illustrated in (a) of FIG. 9, the divided mask 122 is obtained by subjecting a 30 μm-thick invar sheet material 121, which is in roll form, to an etching process for openings 124 and an attachment end portion, and a cutting process for obtaining individual units.

The divided mask 122 includes four opening groups 123, each including the plurality of openings 124. The divided mask 22 has an elongated shape, in which the length of the mask in a first direction corresponding to the left-right direction in the drawing is greater than the length in a second direction that corresponds to the up-down direction in the drawing and is orthogonal to the first direction.

As illustrated in (b) of FIG. 9, the openings 124 of the divided mask 122 are rectangles.

As illustrated in (c) of FIG. 9, the vapor deposition mask 131 includes: a mask frame 132; a plurality of the divided masks 122, which are fixed to the mask frame 132 at predetermined intervals; a plurality of support sheets 133, which are fixed to the mask frame 132 aligned with the second direction in the drawing; and a plurality of cover sheets 134, which are fixed to the mask frame 132 aligned with the first direction in the drawings.

The mask frame 132 is a frame-shaped frame provided with an opening (not illustrated) in a central portion, and the plurality of divided masks 122 are fixed to the mask frame 132 in a manner such that the plurality of openings 124 overlap the centrally provided opening (not illustrated) of the mask frame 132.

In a step of fixing the plurality of divided masks 122 to the mask frame 132, each one of the plurality of divided masks 122 is set in a tensioned state with respect to the first direction in the drawing and fixed.

However, before the divided masks 122 are set in a tensioned state with respect to the first direction in the drawing, as illustrated in (b) of FIG. 9, the openings 124 of the divided masks 122 are rectangles. However, after the divided masks 122 are set in a tensioned state with respect to the first direction in the drawing and fixed to the mask frame 132, as illustrated in (d) of FIG. 9, the openings 124 deform into openings 124E due to the tensile stress when set in a tensioned state, with the length in the first direction in the drawing being elongated and the length in the second direction in the drawing being contracted.

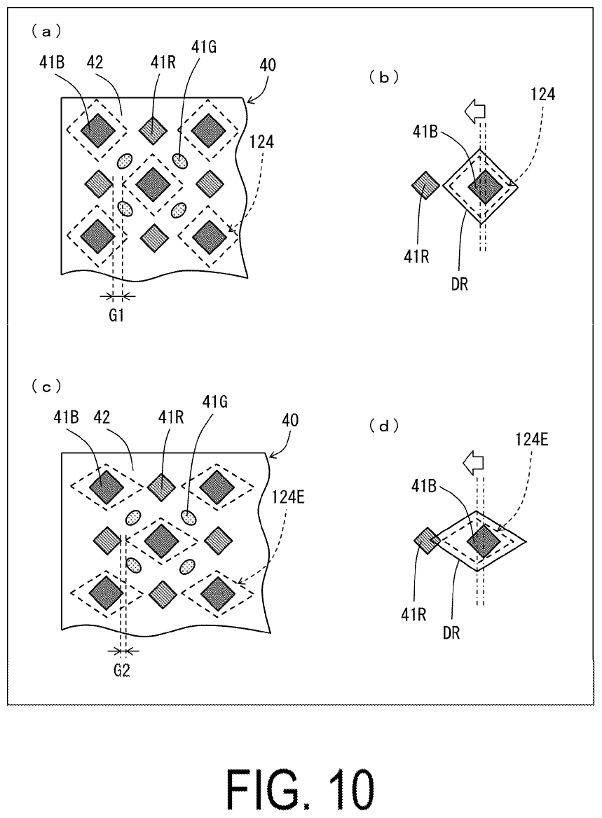

(a) to (d) of FIG. 10 are diagrams for explaining the problem of using the vapor deposition mask 131 according to the Comparative Example illustrated in FIG. 9(c).

(a) of FIG. 10 is a diagram illustrating a case where the plurality of openings 124 of the vapor deposition mask 131 are ideally arranged with respect to the exposure portions 41B of a first electrode provided on an active matrix substrate 40, i.e., the blue pixels of the display device. In a case where the plurality of openings 124 of the vapor deposition mask 131 can be ideally arranged with respect to the blue pixels of the display device, an alignment margin G1 can be secured.

(b) of FIG. 10 is a diagram illustrating a case where a mask misalignment has occurred in the direction of the arrow in the drawing in an arrangement of the plurality of openings 124 of the vapor deposition mask 131 with respect to the blue pixels of the display device. A pattern DR of a vapor deposition film that is formed by the vapor deposition material passing through the plurality of openings 124 of the vapor deposition mask 131 is formed in the outer shadow wider than the opening 124 of the vapor deposition mask 131. As illustrated in (b) of FIG. 10, in a hypothetical case where the shape of the opening 124 of the vapor deposition mask 131 does not deform due to tensile stress when set in a tensioned state, even when mask misalignment within a predetermined range occurs and the pattern DR of the vapor deposition film is formed in the outer shadow wider than the opening 124 of the vapor deposition mask 131 within a predetermined range, the pattern DR of the vapor deposition film is not formed in an exposure portion 41R of the first electrode adjacent to the exposure portions 41B of the first electrode. This is because the alignment margin G1 illustrated in (a) of FIG. 10 is ensured by taking into account in advance that, when forming the vapor deposition film using the vapor deposition mask 131, mask misalignment within a predetermined range may occur and that the pattern DR of the vapor deposition film may be formed in the outer shadow wider than the opening 124 of the vapor deposition mask 131 within a predetermined range.

(c) of FIG. 10 is a diagram illustrating a case where the openings 124E formed by the openings 124 of the vapor deposition mask 131 deforming in shape due to tensile stress when set in a tensioned state are ideally arranged with respect to the exposure portions 41B of a first electrode provided on an active matrix substrate 40, i.e., the blue pixels of the display device. Due to the tensile stress when set in a tensioned state, for the openings 124E of the vapor deposition mask 131, the alignment margin decreases corresponding to the amount the length was elongated, and the alignment margin G1 illustrated in (a) of FIG. 10 first ensured becomes an alignment margin G2. Note that the degree of change in the shape of the openings 124 of the vapor deposition mask 131 due to the tensile stress when set in a tensioned state is dependent on the magnitude of the tensile stress. Thus, because it is different depending on the position of the openings 124 on the vapor deposition mask 131 and different for each divided mask 122 in the vapor deposition mask 131, it is very difficult to include an alignment margin in advance.

(d) of FIG. 10 is a diagram illustrating a case where a mask misalignment has occurred in the direction of the arrow in the drawing in an arrangement of the openings 124E formed by the openings 124 of the vapor deposition mask 131 deforming in shape due to tensile stress when set in a tensioned state with respect to the blue pixels of the display device. As described above, because the alignment margin G2 is formed due to not taking appropriate consideration in advance, the pattern DR of the vapor deposition film is formed in the exposure portion 41R of the first electrode adjacent to the exposure portions 41B of the first electrode due to, when forming the vapor deposition film using the vapor deposition mask 131, mask misalignment within a predetermined range occurring and the pattern DR of the vapor deposition film being formed in the outer shadow wider than the opening 124E of the vapor deposition mask 131 within a predetermined range. This causes a color mixing defect in the exposure portion 41R of the first electrode, i.e., in the red pixel.

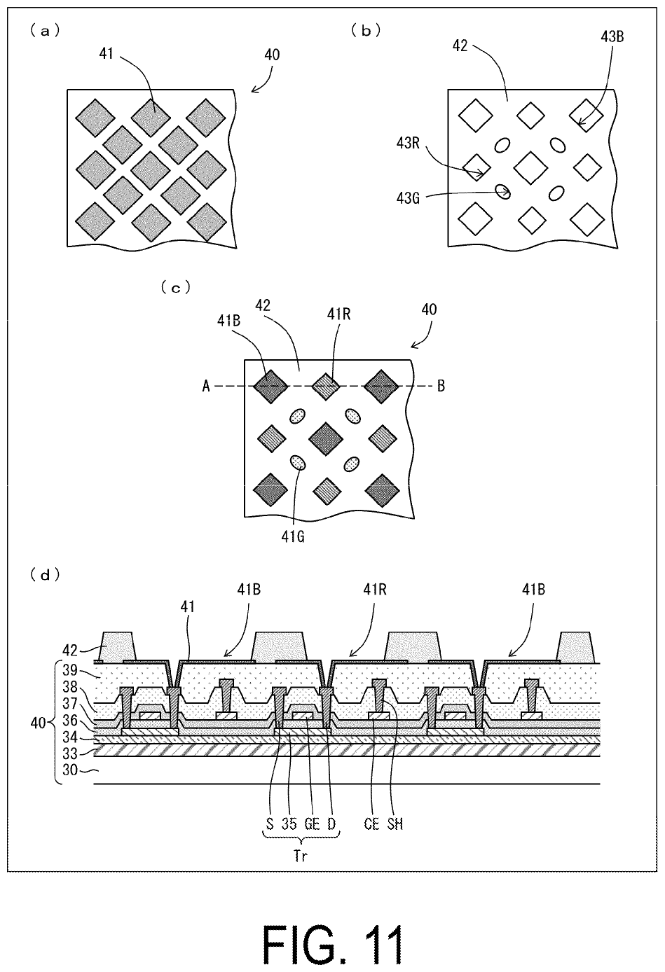

(a) of FIG. 11 is a diagram illustrating the active matrix substrate 40 and a plurality of first electrodes 41 provided on the active matrix substrate 40 provided in the display device according to the present embodiment.

(b) of FIG. 11 is a diagram illustrating an edge cover layer 42 provided on an active matrix substrate. A plurality of rectangular first openings 43B, a plurality of rectangular second openings 43R, and a plurality of third openings 43G are formed in the edge cover layer 42. The plurality of rectangular first openings 43B, the plurality of rectangular second openings 43R, and the plurality of third openings 43G expose each one of the plurality of first electrodes 41 illustrated in (a) of FIG. 11 included in each of the plurality of pixels in the display device of the present embodiment.

(c) of FIG. 11 is a diagram illustrating the plurality of first electrodes 41 provided on the active matrix substrate 40 corresponding to the exposure portions 41R, 41G, and 41B of the first electrode exposed by the plurality of rectangular first openings 43B, the plurality of rectangular second openings 43R, and the plurality of third openings 43G in the edge cover layer 42. The exposure portion 41R of the first electrode is a red pixel of the display device according to the present embodiment, the exposure portions 41G of the first electrode is a green pixel of the display device according to the present embodiment, and the exposure portions 41B of the first electrode is a blue pixel of the display device according to the present embodiment.

Note that, in the present embodiment, as illustrated in (b) and (c) of FIG. 11, the plurality of third openings 43G are formed in a curved shape, and the exposure portions 41G of the first electrode, i.e., the green pixels of the display device of the present embodiment, have a curved shape. However, no such limitation is intended, and the plurality of third openings 43G may be formed in a similar rectangular shape to that of the plurality of rectangular first openings 43B and the plurality of rectangular second openings 43R.

(d) of FIG. 11 is a cross-sectional view of line A-B of (c) of FIG. 11. As illustrated in (d) of FIG. 11, in the active matrix substrate 40, a resin layer 33, a barrier layer (base coat film) 34 that is an inorganic film, a transistor element Tr, and a capacitance element are formed on a glass substrate 30.

Examples of the material of the resin layer 33 include a polyimide resin, an epoxy resin, and a polyamide resin, but are not limited thereto.

The barrier layer 34 is a layer configured to prevent moisture or impurities from reaching the transistor element Tr or a light-emitting element (not illustrated) and can be constituted by, for example, a silicon oxide film, a silicon nitride film or a silicon oxynitride film, or a layered film of these films that are formed using CVD.

The transistor element Tr and the capacitance element are provided as an upper layer overlying the resin layer 33 and the barrier layer 34. The element forming layer including the transistor element Tr and the capacitance element includes a semiconductor film 35, an inorganic insulating film (a gate insulating film) 36 as an upper layer overlying the semiconductor film 35, a gate electrode GE as an upper layer overlying the inorganic insulating film 36, an inorganic insulating film (a first insulating film) 37 as an upper layer overlying the gate electrode GE, a counter electrode CE of a capacitance element as an upper layer overlying the inorganic insulating film 37, an inorganic insulating film (a second insulating film) 38 as an upper layer overlying the counter electrode CE of a capacitance element, a source electrode S as an upper layer overlying the inorganic insulating film 38, a drain electrode D, and a wiring line SH, and an interlayer insulating film 39 as an upper layer overlying the source electrode S, the drain electrode D, and the wiring line SH.

Note that the capacitance element includes the counter electrode CE of a capacitance element formed directly above the inorganic insulating film 37, the inorganic insulating film 37, and a capacitance electrode formed directly below the inorganic insulating film 37 and formed overlapping the counter electrode CE of a capacitance element in the same layer as the layer that forms the gate electrode GE.

The transistor element (thin film transistor (TFT) element) Tr includes, as active elements, the semiconductor film 35, the inorganic insulating film 36, the gate electrode GE, the inorganic insulating film 37, the inorganic insulating film 38, the source electrode S, and the drain electrode D.

The semiconductor film 35 is formed of low-temperature polysilicon (LTPS) or an oxide semiconductor, for example.

The gate electrode GE, the counter electrode CE of a capacitance element, the source electrode S, the drain electrode D, and the wiring line SH are formed of a single-layer film or a layered film of a metal including at least one of aluminum (Al), tungsten (W), molybdenum (Mo), tantalum (Ta), chromium (Cr), titanium (Ti), copper (Cu), and silver (Ag), for example.

The inorganic insulating films 36, 37, and 38 may be formed, for example, by the CVD, of a silicon oxide (SiOx) film, a silicon nitride (SiNx) film, or a silicon oxynitride film, or by a layered film of these.

The interlayer insulating film 39 may be formed of, for example, a coatable photosensitive organic material, such as a polyimide resin, an acrylic resin, or the like.

Note that each one of the plurality of first electrodes 41 provided on the active matrix substrate 40 is electrically connected to the drain electrode D of each one of the plurality of transistor elements Tr.

A display device 50, which has excellent display quality and can prevent color mixing defects, that can be implemented by using a vapor deposition mask 10, which can prevent deformation of openings through which vapor deposition material passes, will be described below with reference to FIGS. 1 to 6.

(a) of FIG. 1 is a diagram illustrating a schematic configuration of a divided mask 2, (b) of FIG. 1 is an enlarged view of a C portion illustrated in (a) of FIG. 1, (c) of FIG. 1 is a diagram illustrating a schematic configuration of the vapor deposition mask 10 according to the present embodiment, and (d) of FIG. 1 is an enlarged view of a D portion illustrated in (c) of FIG. 1.

As illustrated in (a) of FIG. 1, the divided mask 2 is obtained by subjecting a 30 μm-thick invar sheet material 1, which is in roll form, to an etching process for openings 4 and an attachment end portion, and a cutting process for obtaining individual units.

The thickness of the invar sheet material 1 is preferably greater than or equal to 10 μm and less than or equal to 50 μm, and is 30 μm in the present embodiment. However, no such limitation is intended.

Furthermore, in the present embodiment, in the example described above, the divided mask 2 is formed using the invar sheet material 1 as an example. However, no such limitation is intended. The divided mask 2 may be formed using a thin metal sheet material, a thin alloy sheet material, or the like instead of the invar sheet material 1.

The divided mask 2 includes four opening groups 3, each including the plurality of openings 4. The divided mask 2 has an elongated shape, in which the length of the mask in a first direction corresponding to the left-right direction in the drawing is greater than the length in a second direction that corresponds to the up-down direction in the drawing and is orthogonal to the first direction. Note that the shape of the divided mask 2 is an example and no such limitation is intended.

In the present embodiment described below, a single opening group 3 includes openings for forming, for example, a hole transport layer as a rectangular first individual vapor deposition film including a projection portion or a blue light-emitting layer as a rectangular first individual vapor deposition film including a projection portion of a single 5-inch display device. However, no such limitation is intended. It goes without saying that the size of a single opening group 3, the number of openings 4 present in a single opening group 3, and the like differ depending on the size, resolution, and the like of the display device being manufactured.

As illustrated in (b) of FIG. 1, each one of the openings 4 of the divided mask 2 is the rectangular opening 4 including cutout portions 4P. The rectangular opening 4 is an opening in which the cutout portions 4P are provided at locations corresponding to four vertices P of the rectangle. In other words, the rectangular opening 4 is provided with the cutout portions 4P at locations corresponding to opposing vertices P (four vertices P in the present embodiment). Furthermore, the cutout portions 4P are provided to include area outside of the rectangle indicated by a broken line.

Note that in the present embodiment, the portion of the rectangular opening 4 excluding the cutout portion 4P has a size that matches the rectangular opening 124 illustrated in (b) of FIG. 10, but no such limitation is intended.

As illustrated in (c) of FIG. 1, the vapor deposition mask 10 includes: a mask frame 12; the plurality of the divided masks 2, which are fixed to the mask frame 12 at predetermined intervals; a plurality of support sheets 13, which are fixed to the mask frame 12 aligned with the second direction in the drawing; and a plurality of cover sheets 14, which are fixed to the mask frame 12 aligned with the first direction in the drawings.

The mask frame 12 is a frame-shaped frame provided with an opening (not illustrated) in a central portion, and the plurality of divided masks 2 are fixed to the mask frame 12 in a manner such that the rectangular openings 4 overlap the centrally provided opening (not illustrated) of the mask frame 12.

In a step of fixing the plurality of divided masks 2 to the mask frame 12, each one of the plurality of divided masks 2 is set in a tensioned state with respect to the first direction in the drawing and fixed.

In the present embodiment, the plurality of divided masks 2, the plurality of support sheets 13, and the plurality of cover sheets 14 are fixed to the mask frame 12 via welding. However, no such limitation is intended.

As illustrated in (d) of FIG. 1, deformation does not occur in the rectangular openings 4 after the divided masks 2 have been set in a tensioned state with respect to the first direction in the drawing and fixed to the mask frame 12. Thus, in the case of the vapor deposition mask 10, since the openings 4 have a rectangular shape, deformation of the openings through which the vapor deposition material passes can be prevented.

In the present embodiment, in the example described above, the plurality of divided masks 2 including the plurality of rectangular openings 4 are fixed to the mask frame 12. However, no such limitation is intended, and one mask sheet including the plurality of rectangular openings 4 may be fixed to the mask frame 12.

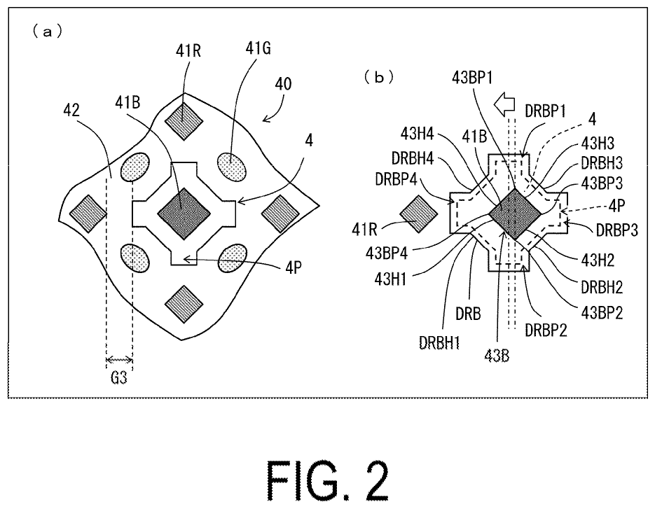

(a) of FIG. 2 is a diagram illustrating a case where the rectangular openings 4 of the vapor deposition mask 10 illustrated in (c) of FIG. 1 are ideally arranged with respect to the exposure portions 41B of a first electrode provided on an active matrix substrate 40, i.e., the blue pixels of the display device according to the present embodiment. In a case where the plurality of rectangular openings 4 of the vapor deposition mask 10 can be ideally arranged with respect to the blue pixels of the display device according to the present embodiment, an alignment margin G3 can be secured.

(a) of FIG. 2 is a diagram illustrating a case where a mask misalignment has occurred in the direction of the arrow in the drawing in an arrangement of the plurality of rectangular openings 4 of the vapor deposition mask 10 with respect to the blue pixels of the display device according to the present embodiment. A pattern DRB of a vapor deposition film that is formed by the vapor deposition material passing through the plurality of rectangular openings 4 of the vapor deposition mask 10 is formed in the outer shadow wider than the rectangular opening 4 of the vapor deposition mask 10.

As illustrated in (b) of FIG. 2, a first projection portion DRBP1, a second projection portion DRBP2, a third projection portion DRBP3, and a fourth projection portion DRBP4 of a first individual vapor deposition film DRB are each patterns of a vapor deposition film formed by vapor deposition material passing through the four cutout portions (the first cutout portion, the second cutout portion, the third cutout portion, and the fourth cutout portion) 4P of the rectangular openings 4 including the cutout portions 4P.

The rectangular first opening 43B of the edge cover layer 42 is an opening surrounded by four sides 43H1 to 43H4 and includes four vertices 43BP1 to 43BP4. The rectangular first individual vapor deposition film DRB is formed on the exposure portion 41B of the first electrode so as to cover the first opening 43B, and, in the first individual vapor deposition film DRB, the projection portions DRBP1 to DRBP4 projecting to the opposite side to the first opening 43B from sections corresponding to the opposing vertices 43BP1 to 43BP4 of the first opening 43B are provided on the edge cover layer

In other words, the first individual vapor deposition film DRB including the first projection portion DRBP1 to fourth projection portion DRBP4 has a size that is greater than the exposure portion 41B of the rectangular first electrode exposed by the rectangular first opening 43B of the edge cover layer 42 and is formed on the exposure portion 41B of the rectangular first electrode and on the edge cover layer 42 near the four vertices 43BP1 to 43BP4 of the rectangular first opening 43B so to overlap the exposure portion 41B of the rectangular first electrode.

Regarding the vapor deposition mask 10 of the present embodiment, in the example described above, in the first individual vapor deposition film DRB, the projection portions DRBP1 to DRBP4 projecting to the opposite side to the first opening 43B from the sections corresponding to the opposing vertices 43BP1 to 43BP4 of the first opening 43B are provided on the edge cover layer 42. However, no such limitation is intended, and in a case of the vapor deposition mask according to the second embodiment and third embodiment described below, in the first individual vapor deposition film, the projection portions projecting to the opposite side to the first opening from the sections corresponding to at least some opposing vertices (two vertices) of the first opening are provided on the edge cover layer.

In the present embodiment, in the example described, the first individual vapor deposition film DRB includes the four sides DRBH1 to DRBH4 parallel with the four side 43H1 to 43H4 of the first opening 43B. However, no such limitation is intended, and the first individual vapor deposition film DRB may include a side parallel with at least one of the four sides 43H1 to 43H4 of the first opening 43B.

As described above, because the shape of the rectangular opening 4 of the vapor deposition mask 10 does not deform due to tensile stress when set in a tensioned state, as illustrated in (b) of FIG. 2, even when mask misalignment within a predetermined range occurs and the first individual vapor deposition film DRB is formed in the outer shadow wider than the rectangular opening 4 of the vapor deposition mask 10 within a predetermined range, the first individual vapor deposition film DRB is not formed in the exposure portion 41R of the first electrode adjacent to the exposure portions 41B of the first electrode. Thus, in the red pixel of the display device according to the present embodiment, a color mixing defect does not occur. This is because the alignment margin G3 illustrated in (a) of FIG. 2 is ensured by taking into account in advance that, when forming the vapor deposition film using the vapor deposition mask 10, mask misalignment within a predetermined range may occur and that the first individual vapor deposition film DRB may be formed in the outer shadow wider than the rectangular opening 4 of the vapor deposition mask 10 within a predetermined range.

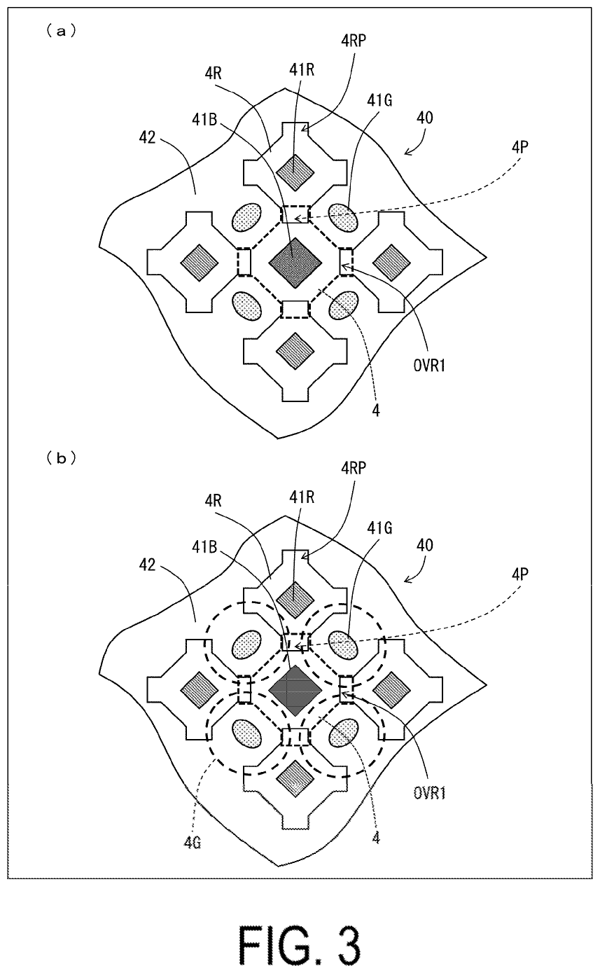

(a) of FIG. 3 is a diagram illustrating an ideal position for disposing the vapor deposition mask 10 illustrated in (c) of FIG. 1 with respect to the blue pixel and an ideal position for disposing another vapor deposition mask including a rectangular opening 4R including a cutout portion 4RP with respect to the red pixel.

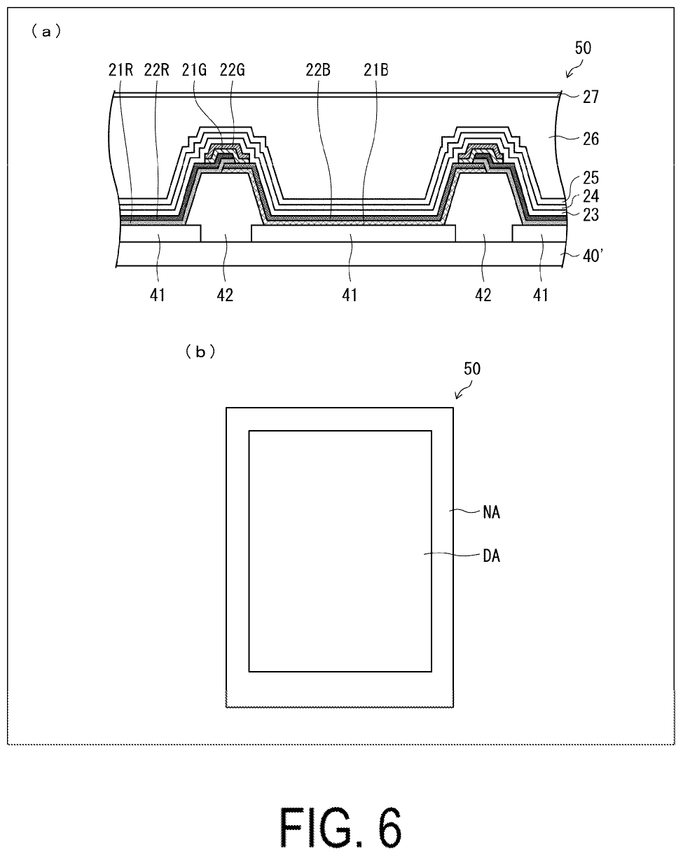

In the present embodiment, in the example described, in a case where the cutout portions 4P of the vapor deposition mask 10, which is used when forming a hole transport layer 21B as the rectangular first individual vapor deposition film including a projection portion and a blue light-emitting layer 22B (see (a) of FIG. 6) as the rectangular first individual vapor deposition film including a projection portion, and the cutout portions 4RP of another vapor deposition mask including the rectangular openings 4R including the cutout portions 4RP, which is used when forming a hole transport layer 21R as a rectangular second individual vapor deposition film including a projection portion and a red light-emitting layer 22R (see (a) of FIG. 6) as the rectangular second individual vapor deposition film including a projection portion, are disposed with their vapor deposition masks in an ideal position, the cutout portion 4P and the cutout portion 4RP at least partially overlap (OVR1 in the drawing). However, no such limitation is intended. In a case where each vapor deposition mask is disposed in an ideal position, the cutout portion 4P of the vapor deposition mask 10 and the cutout portion 4RP of another vapor deposition mask including the rectangular openings 4R including the cutout portions 4RP may not overlap. Note that (a) of FIG. 3 is a diagram illustrating an ideal placement position of the vapor deposition mask 10 and another vapor deposition mask including the rectangular openings 4R including the cutout portions 4RP. Because the process using the vapor deposition mask 10 and the process using another vapor deposition mask including the rectangular openings 4R including the cutout portions 4RP are different processes, when actual performing the processes, the vapor deposition mask 10 and another vapor deposition mask including the rectangular openings 4R including the cutout portions 4RP are not used simultaneously, and the vapor deposition mask 10 and another vapor deposition mask including the rectangular openings 4R including the cutout portions 4RP are not used stacked on one another.

(b) of FIG. 3 is a diagram illustrating an ideal position for disposing the vapor deposition mask 10 with respect to the blue pixel, an ideal position for disposing another vapor deposition mask including the rectangular openings 4R including the cutout portions 4RP with respect to the red pixel, and an ideal position for disposing yet another vapor deposition mask including openings 4G formed in a curved shape with respect to the green pixel.

In the present embodiment, in the example described above, in the yet another vapor deposition mask including a hole transport layer 21G as a third individual vapor deposition film and the openings 4G used when forming a green light-emitting layer 22G (see (a) of FIG. 6) as the third individual vapor deposition film, the openings 4G are formed in a curved shape. However, no such limitation is intended, and the openings 4G may be formed in a rectangular shape.

Also, in the present embodiment, in the example described, a portion where at least the cutout portion 4P and the cutout portion 4RP partially overlap (OVR1 in the drawing) and a portion of the openings 4G portion of the yet another vapor deposition mask including the openings 4G overlap one another. However, no such limitation is intended. Note that (b) of FIG. 3 also, in a similar manner to (a) of FIG. 3, is a diagram illustrating an ideal placement position of the vapor deposition mask 10, another vapor deposition mask including the rectangular openings 4R including the cutout portions 4RP, and yet another vapor deposition mask including the openings 4G. Because the process using the vapor deposition mask 10, the process using another vapor deposition mask including the rectangular openings 4R including the cutout portions 4RP, and the process using yet another vapor deposition mask including the openings 4G are different processes, when actual performing the processes, these vapor deposition masks are not used simultaneously and are not used stacked on one another.

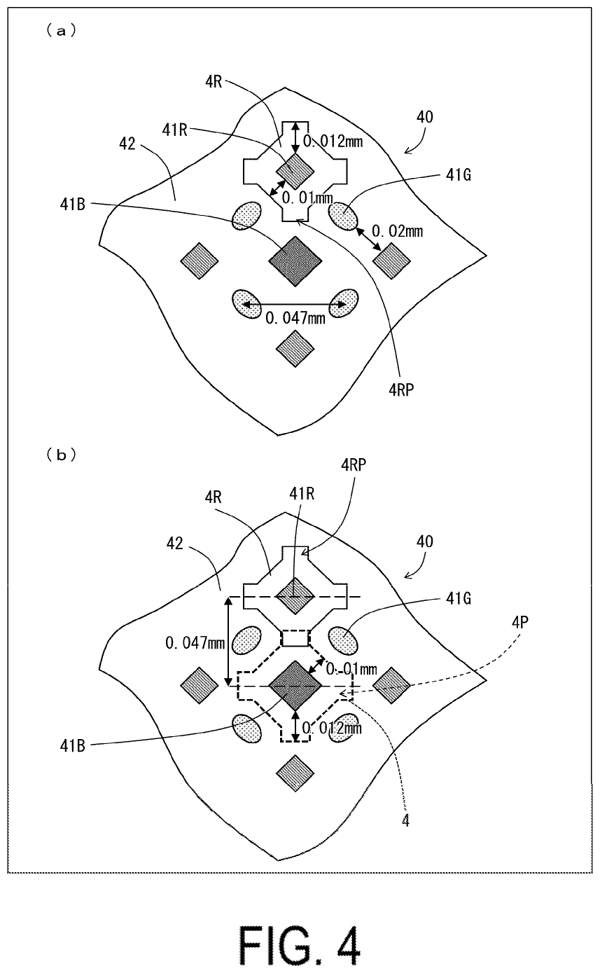

(a) and (b) of FIG. 4 are diagrams illustrating the arrangement of each of the color pixels in the display device of the present embodiment, the size of the rectangular openings 4 including the cutout portions 4P of the vapor deposition mask 10 illustrated in (c) of FIG. 1 compared to the blue pixels, and the size of the rectangular openings 4R including the cutout portion 4RP of another vapor deposition mask of the present embodiment compared to the red pixel. Note that the dimensions illustrated in (a) and (b) of FIG. 4 are examples, and the display device of the present embodiment is not limited to these dimensions.

As illustrated in (a) of FIG. 4, the distance between the centers of two adjacent exposure portions 41G of the first electrode, i.e., two adjacent green pixels, is approximately 0.047 mm, and the distance between an adjacent exposure portion 41R of the first electrode and the exposure portion 41G of the first electrode, i.e., between an adjacent red pixel and a green pixel, is approximately 0.02 mm. In addition, the size of the exposure portion 41R of the first electrode, i.e., the rectangular opening 4R including the cutout portion 4RP of another vapor deposition mask of the present embodiment compared to the red pixel is as follows. The distance between an adjacent one side that constitutes the rectangle of the opening 4R and one side that constitutes the rectangle of the exposure portion 41R of the first electrode is approximately 0.01 mm, and the distance between an adjacent vertex of the rectangle of the exposure portion 41R of the first electrode and the longest side that constitutes the cutout portion 4RP of the opening 4R is approximately 0.012 mm.

Also, as illustrated in (b) of FIG. 4, the distance between an adjacent exposure portion 41R of the first electrode and the exposure portion 41B of the first electrode, i.e., between an adjacent red pixel and a blue pixel, is approximately 0.047 mm. In addition, the size of the exposure portion 41B of the first electrode, i.e., the rectangular opening 4 including the cutout portion 4P of the vapor deposition mask 10 of the present embodiment compared to the blue pixel is as follows. The distance between an adjacent one side that constitutes the rectangle of the opening 4 and one side that constitutes the rectangle of the exposure portion 41B of the first electrode is approximately 0.01 mm, and the distance between an adjacent vertex of the rectangle of the exposure portion 41B of the first electrode and the longest side that constitutes the cutout portion 4P of the opening 4 is approximately 0.012 mm.

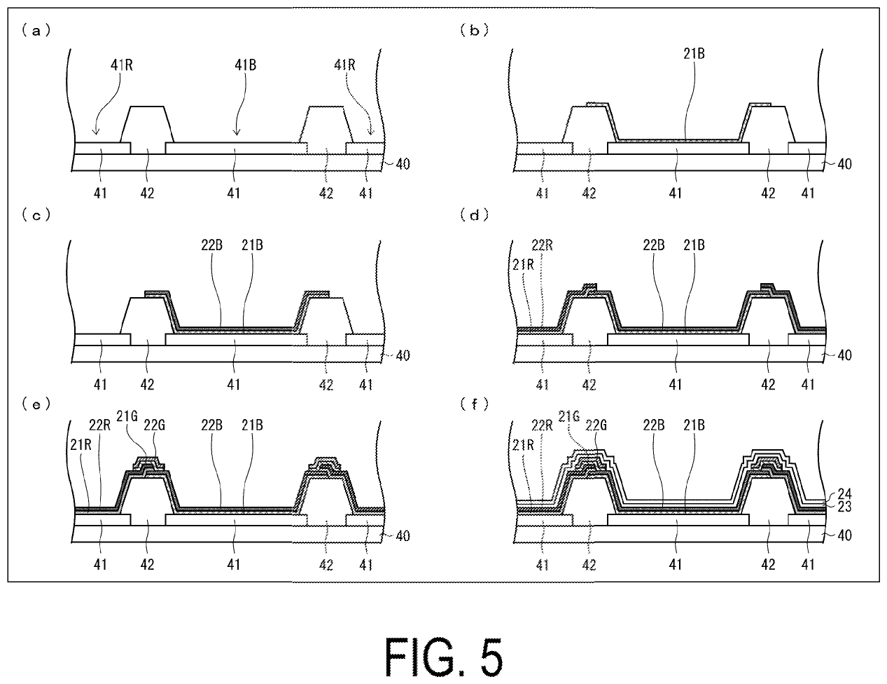

(a) to (f) of FIG. 5 are diagrams for describing the process for forming a vapor deposition film using the vapor deposition mask 10 illustrated in (c) of FIG. 1, another vapor deposition mask including the rectangular openings 4R including the cutout portions 4RP according to the present embodiment, and yet another vapor deposition mask including the openings 4G, in this order.

As illustrated in (a) of FIG. 5, the plurality of first electrodes 41 provided on the active matrix substrate 40 correspond to the exposure portions 41R and 41B of the first electrode exposed by the plurality of rectangular first openings 43B, the plurality of rectangular second openings 43R, and the plurality of third openings 43G in the edge cover layer 42.

(b) of FIG. 5 illustrates a case in which the hole transport layer 21B is formed as the rectangular first individual vapor deposition film including a projection portion using the vapor deposition mask 10 illustrated in (c) of FIG. 1.

(c) of FIG. 5 illustrates a case in which the blue light-emitting layer 22B is formed as the rectangular first individual vapor deposition film including a projection portion using a vapor deposition mask with the same shape as the vapor deposition mask 10 used in the example of (b) of FIG. 5. The hole transport layer 21B and the blue light-emitting layer 22B are layered bodies.

(d) of FIG. 5 illustrates a case in which the hole transport layer 21R has been formed as the rectangular second individual vapor deposition film including a projection portion using another vapor deposition mask including the rectangular openings 4R including the cutout portions 4RP of the present embodiment, and the red light-emitting layer 22R has been formed as the rectangular second individual vapor deposition film including a projection portion using a vapor deposition mask with the same shape as another vapor deposition mask including the rectangular openings 4R including the cutout portions 4RP. The hole transport layer 21R and the red light-emitting layer 22R are layered bodies. Note that, in a portion on the edge cover layer 42, the hole transport layer 21B, the blue light-emitting layer 22B, the hole transport layer 21R, and the red light-emitting layer 22R overlap one another.

(e) of FIG. 5 illustrates a case in which the hole transport layer 21G has been formed as the third individual vapor deposition film using yet another vapor deposition mask including the openings 4G, and the green light-emitting layer 22G has been formed as the third individual vapor deposition film using a vapor deposition mask with the same shape as the another vapor deposition mask including the openings 4G. The hole transport layer 21G and the green light-emitting layer 22G are layered bodies. Note that, in a portion on the edge cover layer 42, the hole transport layer 21B, the blue light-emitting layer 22B, the hole transport layer 21R, the red light-emitting layer 22R, the hole transport layer 21G, and green light-emitting layer 22G overlap one another.

(f) of FIG. 5 illustrates a case in which an electron transport layer 23 is formed as a common layer and a second electrode 24 is formed as a common layer.

As described in the example described above, in the present embodiment, the vapor deposition mask 10 illustrated in (c) of FIG. 1, which is a vapor deposition mask with openings that do not deform in shape due to tensile stress when the hole transport layer 21B, the blue light-emitting layer 22B, the hole transport layer 21R, and the red light-emitting layer 22R are set in a tensioned state because the hole transport layer 21G and the green light-emitting layer 22G are formed using the yet another vapor deposition mask including the openings 4G formed in a curved shape, and the another vapor deposition mask including the rectangular openings 4R including the cutout portions 4RP of the present embodiment are used. However, no such limitation is intended. Furthermore, the yield of the display device can be improved by using a vapor deposition mask with openings that do not deform in shape due to tensile stress when components are set in a tensioned state.

Note that in the present embodiment, the hole transport layer 21B, the hole transport layer 21R, and the hole transport layer 21G are made of the same material. However, no such limitation is intended, and the hole transport layer 21B, the hole transport layer 21R, and the hole transport layer 21G may be made of different materials.

Note that hole transport layers 21B, 21R, 21G, each color light-emitting layer 22B, 22R, 22G, and the electron transport layer 23 formed between the first electrodes 41 and the second electrode 24 are referred to as function layers. Note that in the function layers, as necessary, a hole injection layer or an electron injection layer may be further added, and the hole transport layers 21B, 21R, 21G or the electron transport layer 23 may be omitted. Note that the first electrode 41, the functional layers described above, and the second electrode 24 constitute a light-emitting element layer.

(a) of FIG. 6 is a cross-sectional view of a display region DA of the display device 50 according to the present embodiment. (b) of FIG. 6 is a plan view of the display device 50 according to the present embodiment.

As illustrated in (a) of FIG. 6, the display device 50 according to the present embodiment includes a light-transmitting sealing layer, and the light-transmitting sealing layer includes a first inorganic sealing film 25 covering the second electrode 24 as a common layer, an organic sealing film 26 formed as an upper layer overlying the first inorganic sealing film 25, and a second inorganic sealing film 27 covering the organic sealing film 26. The light-transmitting sealing layer inhibits foreign matter, such as water and oxygen, from entering into the light-emitting element.

Each of the first inorganic sealing film 25 and the second inorganic sealing film 27 may be formed of, for example, a silicon oxide film, a silicon nitride film, or a silicon oxynitride film, or of a layered film of these, formed through CVD. The organic sealing film 26 is thicker than the first inorganic sealing film 25 and the second inorganic sealing film 27, is a light-transmitting organic film, and can be formed of a coatable photosensitive organic material such as a polyimide resin or an acrylic resin.

In the present embodiment, in the example described above, a sealing layer is formed by one organic film layer and two inorganic film layers, the organic sealing film 26 being provided between the first inorganic sealing film 25 and the second inorganic sealing film 27. However, no such limitation is intended, and the light-transmitting sealing layer may be formed by only one or more inorganic film layer or only one or more organic film layer, or may be formed by two or more inorganic films and two or more organic films.

Note that the edge cover layer 42 can be formed of a coatable photosensitive organic material, such as a polyimide resin or an acrylic resin, for example.

The first electrodes 41 are formed by, for example, layering Indium Tin Oxide (ITO) and an alloy including silver (Ag). However, the composition is not particularly limited, and it is only required that electrical conductivity and light reflectivity can be ensured. Also, the second electrode 24 can be formed by a light-transmitting conductive material such as Indium Tin Oxide (ITO) and Indium Zinc Oxide (IZO). However, the composition is not particularly limited, and it is only required that electrical conductivity and light-transmitting properties can be ensured.

Note that in the present embodiment, in the example described, the display device 50 is a top-emitting display device. However, no such limitation is intended, and the display device 50 may be a bottom-emitting display device with the second electrode 24 having light reflectivity and the first electrodes 41 having light-transmitting properties.

Note that the active matrix substrate 40′ illustrated in (a) of FIG. 6 is flexible. Although the active matrix substrate 40 illustrated in (d) of FIG. 11 includes the glass substrate 30, the active matrix substrate 40′ is an active matrix substrate to which a base substrate, which is a flexible substrate, is attached via an adhesive layer instead of the glass substrate 30. Note that an example of the material of the base substrate includes polyethylene terephthalate (PET), but the material is not limited thereto.

Note that the display device 50 including the active matrix substrate 40′ can be manufactured by, after forming the first inorganic sealing film 25, the organic sealing film 26, and the second inorganic sealing film 27 illustrated in (a) of FIG. 6 on the active matrix substrate 40 illustrated in (d) of FIG. 10, irradiating the resin layer 33 with laser beams through the glass substrate 30 and peeling the glass substrate 30 from the resin layer 33, and thereafter bonding a base substrate, which is a flexible substrate, to the surface where the glass substrate 30 was peeled off from the resin layer 33 via an adhesive layer. Furthermore, the display device 50 may be manufactured by omitting the process of bonding the base substrate, which is a flexible substrate, via an adhesive layer and using the resin layer 33 as a flexible substrate as is. Note that examples of the adhesive layer include an optical clear adhesive (OCA) or an optical clear resin (OCR), but are not limited thereto.

As illustrated in (b) of FIG. 6, the display device 50 includes the display region DA and a frame region NA formed around the display region DA. The pixels of each color are provided in the display region DA.

### Second Embodiment

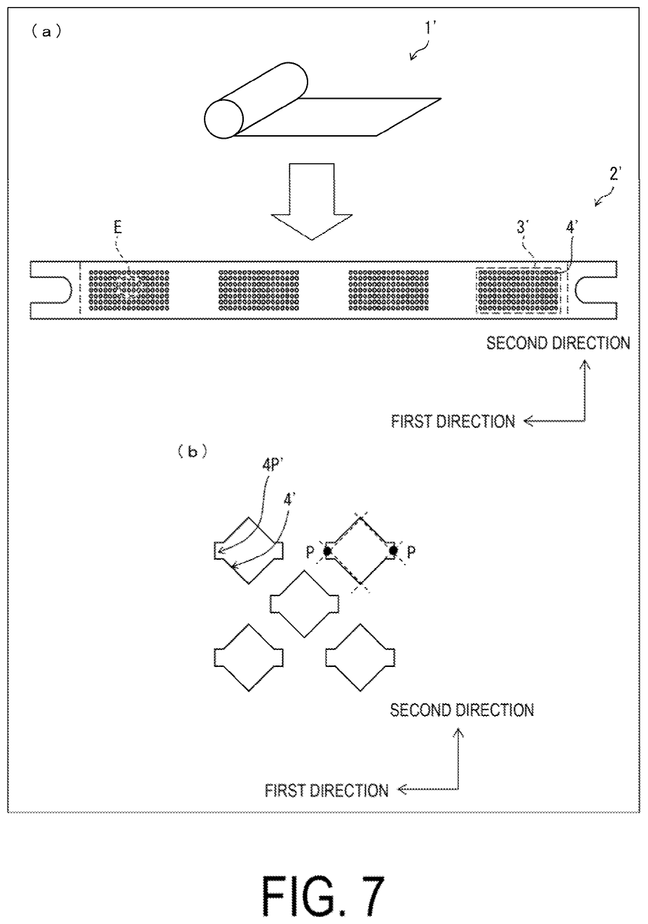

Next, with reference to FIG. 7, a second embodiment of the disclosure will be described. Rectangular openings 4′ including cutout portions 4P′ included in divided masks 2′ of a vapor deposition mask according to the present embodiment are the same as that described in the first embodiment, except that only two cutout portions 4P′ are provided, and the two cutout portions (a first cutout portion and a second cutout portion) 4P′ are disposed opposite one another in the first direction which is the direction parallel with direction the divided masks 2′ are set in a tensioned state. For convenience of description, members having the same functions as those of the members illustrated in the diagrams in the first embodiment are denoted by the same reference numerals, and descriptions thereof will be omitted.

(a) of FIG. 7 is a diagram illustrating a schematic configuration of the divided mask 2′, and (b) of FIG. 7 is an enlarged view of an E portion illustrated in (a) of FIG. 7.

Note that in the present embodiment, the divided mask 2′ is manufactured using a metal sheet material 1′. Note that the divided mask 2′ includes a plurality of opening groups 3′ including the rectangular openings 4′ that include the plurality of cutout portions 4P′.

Also, as illustrated in (b) of FIG. 7, in the rectangular openings 4′ including cutout portions 4P′ included in the divided mask 2′, only the two cutout portions 4P′ are provided, and the two cutout portions (the first cutout portion and the second cutout portion) 4P′ are disposed opposite one another in the first direction which is the direction parallel with direction the divided masks 2′ are set in a tensioned state. In other words, the rectangular opening 4′ is provided with the cutout portions 4P′ at sections corresponding to at least some opposing vertices P (in the present embodiment, two vertices P arranged along the first direction in the drawing). Furthermore, the cutout portions 4P′ are provided to include area outside of the rectangle indicated by a broken line. Thus, also in a case in which the vapor deposition mask is manufactured using the divided mask 2′, deformation due to tensile stress when set in a tensioned state does not occur in the shape of the rectangular openings 4′ including the cutout portions 4P′ of the vapor deposition mask, allowing a vapor deposition mask that prevents deformation in the openings through which vapor deposition material passes to be obtained. Furthermore, the yield of the display device can be improved by using such a vapor deposition mask.

### Third Embodiment

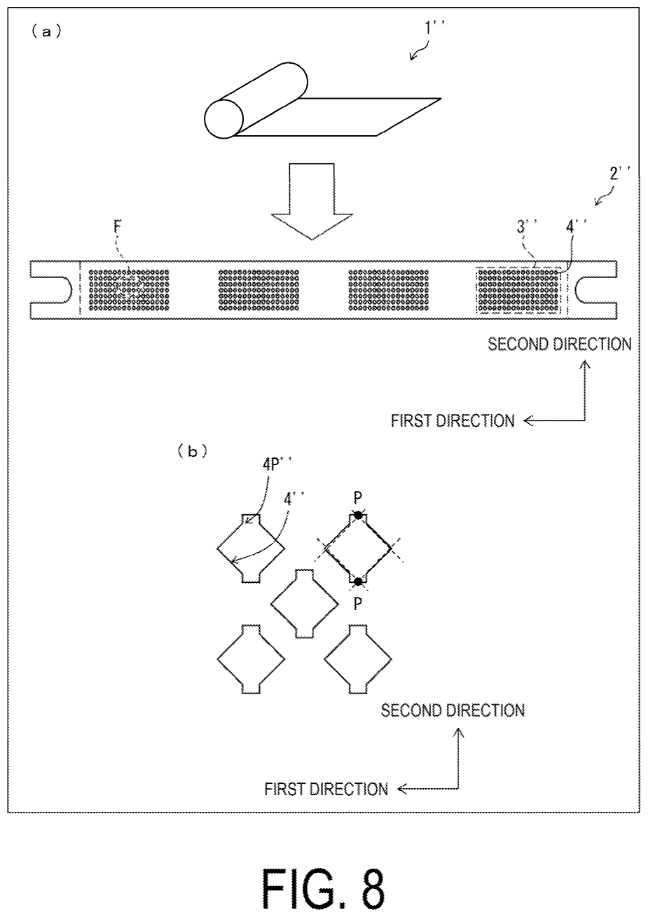

Next, with reference to FIG. 8, a third embodiment of the disclosure will be described. Rectangular openings 4″ including cutout portions 4P″ included in divided masks 2″ of a vapor deposition mask according to the present embodiment are the same as that described in the first embodiment, except that only two cutout portions 4P″ are provided, and the two cutout portions (a first cutout portion and a second cutout portion) 4P″ are disposed opposite one another in the second direction orthogonal to the first direction which is the direction parallel with direction the divided masks 2″ are set in a tensioned state. For convenience of description, members having the same functions as those of the members illustrated in the diagrams in the first embodiment are denoted by the same reference numerals, and descriptions thereof will be omitted.

(a) of FIG. 8 is a diagram illustrating a schematic configuration of the divided mask 2″, and (b) of FIG. 8 is an enlarged view of an F portion illustrated in (a) of FIG. 8.

Note that in the present embodiment, the divided mask 2″ is manufactured using an alloy sheet material 1″. Note that the divided mask 2″ includes a plurality of opening groups 3″ including the rectangular openings 4″ that include the plurality of cutout portions 4P″.

Also, as illustrated in (b) of FIG. 8, in the rectangular openings 4″ including cutout portions 4P″ included in the divided mask 2″, only the two cutout portions 4P″ are provided, and the two cutout portions (the first cutout portion and the second cutout portion) 4P″ are disposed opposite one another in the second direction orthogonal to the first direction which is the direction parallel with direction the divided masks 2″ are set in a tensioned state. In other words, the rectangular opening 4″ is provided with the cutout portions 4P″ at sections corresponding to at least some opposing vertices P (in the present embodiment, two vertices P arranged along the second direction in the drawing). Furthermore, the cutout portions 4P″ are provided to include area outside of the rectangle indicated by a broken line. Thus, also in a case in which the vapor deposition mask is manufactured using the divided mask 2″, deformation due to tensile stress when set in a tensioned state does not occur in the shape of the rectangular openings 4″ including the cutout portions 4P″ of the vapor deposition mask, allowing a vapor deposition mask that prevents deformation in the openings through which vapor deposition material passes to be obtained. Furthermore, the yield of the display device can be improved by using such a vapor deposition mask.

### Supplement

### First Aspect

A display device provided with a display region including a plurality of pixels and a frame region around the display region, includes:

an active matrix substrate including a transistor element;

a light-emitting element layer provided on the active matrix substrate and including a plurality of first electrodes, a function layer, and a second electrode in this order from the active matrix substrate side; and

a sealing layer provided on the light-emitting element layer,

wherein the light-emitting element layer further includes an edge cover layer configured to cover an end portion of each one of the plurality of first electrodes,

the edge cover layer includes a plurality of openings configured to expose the plurality of first electrodes included in the plurality of pixels,

the plurality of openings include a first opening with a rectangular shape,

a first individual vapor deposition film with a rectangular shape is formed on the first electrode covering the first opening, and

in the first individual vapor deposition film, projection portions projecting from sections corresponding to at least some opposing vertices of the first opening to an opposite side to the first opening are provided on the edge cover layer.

### Second Aspect

In the display device according to the first aspect, the first individual vapor deposition film includes a side parallel with at least one side from among four sides of the first opening.

Third Aspect

In the display device according to the first or second aspect, the first individual vapor deposition film includes four sides parallel with four sides of the first opening.

### Fourth Aspect

In the display device according to any one of the first to third aspects,

the plurality of openings include a second opening with a rectangular shape;

the second individual vapor deposition film with a rectangular shape is formed on the first electrode covering the second opening; and

in the first individual vapor deposition film, projection portions projecting from sections corresponding to opposing vertices of the first opening to an opposite side to the first opening are provided on the edge cover layer.

### Fifth Aspect

In the display device according to the fourth aspect, the projection portions of the first individual vapor deposition film and the projection portions of the second individual vapor deposition film overlap one another on the edge cover layer.

### Sixth Aspect

In the display device according to the fourth or fifth aspect,

the first individual vapor deposition film includes one of a red light-emitting layer or a blue light-emitting layer; and

the second individual vapor deposition film includes the other of a red light-emitting layer or a blue light-emitting layer.

### Seventh Aspect

In the display device according to the fourth or fifth aspect,

the first individual vapor deposition film and the second individual vapor deposition film include a hole transport layer made of identical material.

### Eighth Aspect

In the display device according to the fourth or fifth aspect,

the plurality of openings include a third opening;

a third individual vapor deposition film is formed on the first electrode covering the third opening; and

in adjacent pixels of the plurality of pixels, the projection portions of the first individual vapor deposition film, the projection portions of the second individual vapor deposition film, and the third individual vapor deposition film overlap one another on the edge cover layer.

### Ninth Aspect

In the display device according to the eighth aspect,

the first individual vapor deposition film includes one of a red light-emitting layer or a blue light-emitting layer;

the second individual vapor deposition film includes the other of a red light-emitting layer or a blue light-emitting layer; and

the third individual vapor deposition film includes a green light-emitting layer.

### Tenth Aspect

In the display device according to the eighth or ninth aspect,

the first individual vapor deposition film, the second individual vapor deposition film, and the third individual vapor deposition film include a hole transport layer made of identical material.

### Eleventh Aspect

A vapor deposition mask includes:

a mask frame with a frame-like shape; and

a mask sheet including a plurality of openings, the mask sheet being fixed to the mask frame,

wherein the plurality of openings of the mask sheet are openings with a rectangular shape, and

in the openings, cutout portions are provided at sections corresponding to at least some opposing vertices.

### Twelfth Aspect

In the vapor deposition mask according to the eleventh aspect,

the cutout portions include a first cutout portion and a second cutout portion; and

the first cutout portion and the second cutout portion are provided opposing one another in a first direction, which is a direction parallel with a direction the mask sheet is set in a tensioned state.

### Thirteenth Aspect

In the vapor deposition mask according to the eleventh aspect,

the cutout portions include a third cutout portion and a fourth cutout portion; and

the third cutout portion and the fourth cutout portion are provided opposing one another in a second direction orthogonal to a first direction, which is a direction parallel with a direction the mask sheet is set in a tensioned state.

### Fourteenth Aspect

In the vapor deposition mask according to the eleventh aspect,

the cutout portions include a first cutout portion, a second cutout portion, a third cutout portion, and a fourth cutout portion;

the first cutout portion and the second cutout portion are provided opposing one another in a first direction, which is a direction parallel with a direction the mask sheet is set in a tensioned state; and

the third cutout portion and the fourth cutout portion are provided opposing one another in a second direction orthogonal to the first direction.

### Additional Items

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

### INDUSTRIAL APPLICABILITY

The disclosure has application towards display devices and vapor deposition masks.

1. A display device provided with a display region including a plurality of pixels and a frame region around the display region, comprising:
an active matrix substrate including a transistor element;
a light-emitting element layer provided on the active matrix substrate and including a plurality of first electrodes, a function layer, and a second electrode in this order from the active matrix substrate side; and
a sealing layer provided on the light-emitting element layer,
wherein the light-emitting element layer further includes an edge cover layer configured to cover an end portion of each one of the plurality of first electrodes,
the edge cover layer includes a plurality of openings configured to expose the plurality of first electrodes included in the plurality of pixels,
the plurality of openings include a first opening with a rectangular shape,
a first individual vapor deposition film with a rectangular shape is formed on the first electrode covering the first opening, and
in the first individual vapor deposition film, projection portions projecting from sections corresponding to at least some opposing vertices of the first opening to an opposite side to the first opening are provided on the edge cover layer.

2. The display device according to claim 1,
wherein the first individual vapor deposition film includes a side parallel with at least one side from among four sides of the first opening.

3. The display device according to claim 1,
wherein the first individual vapor deposition film includes four sides parallel with four sides of the first opening.

4. The display device according to claim 1,
wherein the plurality of openings include a second opening with a rectangular shape;
a second individual vapor deposition film with a rectangular shape is formed on the first electrode covering the second opening; and
in the second individual vapor deposition film, projection portions projecting from sections corresponding to opposing vertices of the second opening to an opposite side to the second opening are provided on the edge cover layer.

5. The display device according to claim 4,
wherein the projection portions of the first individual vapor deposition film and the projection portions of the second individual vapor deposition film overlap one another on the edge cover layer.

6. The display device according to claim 4,
wherein the first individual vapor deposition film includes one of a red light-emitting layer or a blue light-emitting layer; and
the second individual vapor deposition film includes the other of a red light-emitting layer or a blue light-emitting layer.

7. The display device according to claim 4,
wherein the first individual vapor deposition film and the second individual vapor deposition film include a hole transport layer made of identical material.

8. The display device according to claim 4,
wherein the plurality of openings include a third opening;
a third individual vapor deposition film is formed on the first electrode covering the third opening; and
in adjacent pixels of the plurality of pixels, the projection portions of the first individual vapor deposition film, the projection portions of the second individual vapor deposition film, and the third individual vapor deposition film overlap one another on the edge cover layer.

9. The display device according to claim 8,
wherein the first individual vapor deposition film includes one of a red light-emitting layer or a blue light-emitting layer;
the second individual vapor deposition film includes the other of a red light-emitting layer or a blue light-emitting layer; and
the third individual vapor deposition film includes a green light-emitting layer.

10. The display device according to claim 8,
wherein the first individual vapor deposition film, the second individual vapor deposition film, and the third individual vapor deposition film include a hole transport layer made of identical material.

11. (canceled)

12. (canceled)

13. (canceled)

14. (canceled)
